(19) United States
(12) Patent Application Publication
(10) Pub. No.: US 2010/0060502 A1
(43) Pub. Date: Mar. 11, 2010

(54) A/D CONVERTER

(75) Inventors: Akira Toyama, Musashino-shi (JP); Yasukazu Akasaka, Musashino-shi (JP); Chie Sato, Musashino-shi (JP); Tsuyoshi Yakihara, Musashino-shi (JP); Mamoru Sanagi, Musashino-shi (JP); Akira Miura, Musashino-shi (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: YOKOGAWA ELECTRIC CORPORATION, Tokyo (JP)

(21) Appl. No.: 12/540,525

(22) Filed: Aug. 13, 2009

(30) Foreign Application Priority Data
Sep. 5, 2008 (JP) 2008-228498

(51) Int. Cl. H03M 1/12

(52) U.S. Cl. 341/159

(57) ABSTRACT

There is provided an A/D converter capable of changing specification and function of the A/D converter with the use of a programmable circuit by combining comparators with the programmable circuit. The A/D converter comprises a parallel-connected comparison circuit including a plurality of comparators, an analog signal being inputted to one of input terminals of the respective comparators while respective predetermined reference voltages being inputted to the other of the input terminals of the respective comparators, and a digital processing circuit for receiving output signals from the parallel-connected comparison circuit, and executing predetermined digital processing as set on the basis of a program.

### FIELD OF THE INVENTION

The present invention relates to an A/D converter, and more specifically, to an A/D converter capable of flexibly coping with a change in specification

### BACKGROUND OF THE INVENTION

Electronic equipment in various sectors, for use in household appliances, audio, video, industrial automatic control, measurements, and so forth, has come to be digitized in recent years, so that signal processing that was executed with an analog signal in the past has since been replaced by signal processing with a digital signal. Thus, with the electronic equipment as digitized, an input analog signal is converted into a digital signal by use of an A/D converter, and subsequently, data processing, such as various operations, correction, and so forth, is carried out.

Now, for an A/D converter, use is made of various types including a parallel-connected type (flash type), successive approximation type, an integral type, ΣΔ type, and so forth. The A/D converter is mostly integrated as an A/D converter for executing analog-to-digital conversion according to a specification preset on the basis of the respective types. With an A/D converter built in a CPU, its specification is fixed as set beforehand.

FIG. 13 is a block diagram showing an example of a conventional flash type A/D converter. The flash type A/D converter is based on a method whereby a plurality (n units) of comparators 1, corresponding to quantizing level numbers, are connected in parallel with each other to be concurrently operated, and for example, in the case of 4-bit resolution, 15 units of the comparators 1 are parallel-connected while in the case of 8-bit resolution, 255 units of the comparators 1 are parallel-connected. A common analog signal Ain from a common analog input terminal 2 is concurrently inputted to one of input terminals of each of all the comparators 1. Inputted to the other of the input terminals of each of all the comparators 1 are respective output voltages of resistance-type potential dividers 3 that output a plurality (n varieties) of reference voltages Vr1 to Vrn differing from each other by the voltage resolution of, for example, least significant bit (LSB).

In so doing, the comparators 1 each output “1” if the reference voltage is lower than the analog signal Ain, while outputting “0” if the reference voltage is higher than the analog signal Ain. A data pattern (11 . . . 100 . . . 0) having the number of “1s” in succession according to magnitude of a value of the analog signal Ain as in the case of a bar graph called a thermometer code is obtained by aligning respective outputs of all the comparators 1. The data pattern is inputted to a encoder 6 via each of latch circuits 5 for aligning output timings on the basis of a common clock CLK outputted from a clock generation circuit 4 to thereby find a transition point between “1” and “0” of the thermometer code, whereupon a binary code as converted is outputted to a digital signal output terminal Dout 7.

Patent Document 1 relates to an A/D converter capable of freely setting a quantization width, and an image display device using the A/D converter.
[Patent Document 1] JP 2002-217733 A

### SUMMARY OF THE INVENTION

The flash type A/D converter shown in FIG. 13 can be operated very fast since it is capable of executing conversion simply on the basis of comparison determination time by the respective comparators 1, however, there is a problem in that the flash type A/D converter turns out expensive because use is made of the plurality (n units) of the comparators 1. Further, if bit numbers are increased, this will lead to an increase in the number of the comparators, causing a problem of an increase in the scale of an A/D converter.

Further, because an A/D converter is made up on a printed wiring board by combining it with one-chip IC, or a plurality of ICs, and discrete elements, there is a problem in that specification of the A/D converter comes to be fixed.

Still further, there is available an A/D converter with a programmable gain amp (PGA), and a switch (multiplexer), built therein, however, it represents the case where a function for analog signal processing is added to the A/D converter, so that there is a problem in that the basic performance of the A/D converter cannot be changed.

Yet further, there is a problem in that in case there occurs a change in configuration and circuit of a system with an A/D converter built therein, it becomes necessary to redesign a processing circuit for an analog signal to be inputted to the A/D converter so as to be adaptable to a change in specification, and to replace the A/D converter.

The present invention has been developed to solve those problems, and it is therefore an object of the invention to provide an A/D converter capable of changing specification and function of the A/D converter with the use of a programmable circuit by combining comparators with the programmable circuit.

In accordance with one aspect of the invention, there is provided an A/D converter comprising a parallel-connected comparison circuit including a plurality of comparators, an analog signal being inputted to one of input terminals of the respective comparators while respective predetermined reference voltages being inputted to the other of the input terminals of the respective comparators, and a digital processing circuit for receiving output signals from the parallel-connected comparison circuit, and executing predetermined digital processing as set on the basis of a program.

The predetermined reference voltages may be a common predetermined voltage.

Analog voltages differing from each other may be inputted to one of the input terminals of the respective comparators.

The digital processing circuit is preferably a programmable circuit.

The digital processing circuit preferably executes digital processing including at least any of code conversion, linearity correction, and filtering process.

The digital processing circuit may be made up of FPGA.

The digital processing circuit may be made up of CPLD.

The parallel-connected comparison circuit and the digital processing circuit may be mounted on a common semiconductor substrate.

By so doing, it is possible to provide an A/D converter wherein digital processing content of a programmable circuit can be freely changed according to application.

### BRIEF DESCRIPTION OF THE DRAWINGS

FIG. 1 is a block diagram showing one embodiment of an A/D converter according to the invention;

FIG. 2 is a block diagram of an A/D converter showing a specific example of interleaving;

FIG. 3 is a waveform chart of the example shown in FIG. 2;

FIG. 4 is a block diagram of an A/D converter showing another specific example of interleaving;

FIG. 5 is a waveform chart of the example shown in FIG. 4;

FIG. 6 is a block diagram of an A/D converter showing still another specific example of interleaving;

FIG. 7 is a waveform chart of the example shown in FIG. 6;

FIG. 8 is a block diagram of an A/D converter showing yet another specific example of interleaving;

FIG. 9 is waveform chart of the example shown in FIG. 8;

FIG. 10 is a block diagram showing an example of an optical A/D converter;

FIG. 11 is waveform chart of the example shown in FIG. 10;

FIG. 12 is a block diagram showing an example of an optical A/D converter; and

FIG. 13 is a block diagram showing an example of a conventional flash type A/D converter.

### DETAILED DESCRIPTION OF THE PREFERRED EMBODIMENTS

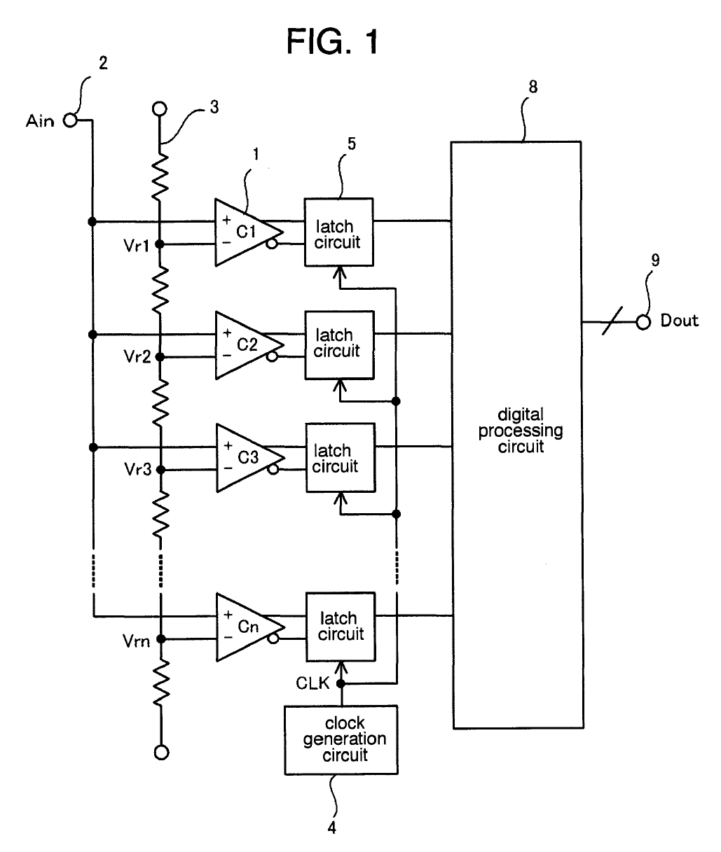

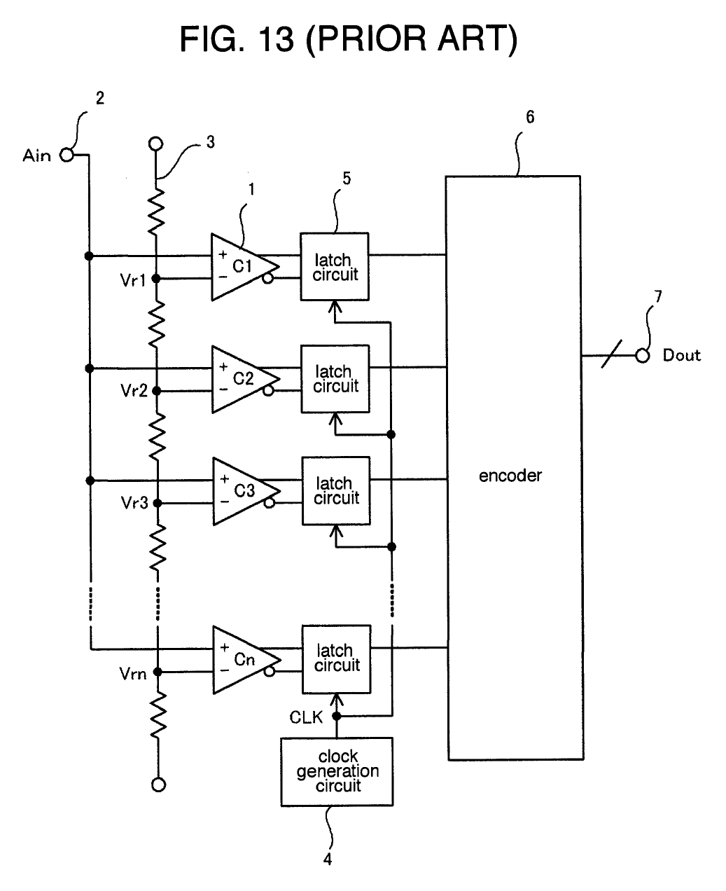

Now, an A/D converter according to the invention is described hereinafter with reference to the accompanying drawings. FIG. 1 is a block diagram showing one embodiment of an A/D converter according to the invention. In the figure, parts corresponding to those in FIG. 13 are denoted by like reference numerals. FIG. 1 differs from FIG. 13 in that a digital processing circuit 8 in FIG. 1 is substituted for the encoder 6 in FIG. 13.

More specifically, a plurality (n units) of comparators 1, corresponding to quantizing level numbers, (for example, in the case of resolution 8-bit, 255 units of the comparators 1) are parallel-connected, and a common analog signal Ain from a common analog input terminal 2 is concurrently inputted to one of input terminals of each of all the comparators 1 while respective output voltages of resistance-type potential dividers 3 that output a plurality (n varieties) of reference voltages Vr1 to Vrn, differing from each other by the voltage resolution of, for example, least significant bit (LSB), respectively, are inputted to the other of the input terminals of each of all the comparators 1.

Then, the comparators 1 each output “1” if the reference voltage is lower than the analog signal Ain, outputting “0” if the reference voltage is higher than the analog signal Ain. As is the case with FIG. 13, by aligning respective outputs of all the comparators 1, there is obtained a data pattern of a thermometer code, having “1s” in succession according to the magnitude of the value of the analog signal Ain. The data pattern is inputted to the digital processing circuit 8 via each of latch circuits 5 for aligning output timings on the basis of a common clock outputted from a clock generation circuit 4.

The digital processing circuit 8 executes digital signal processing against respective digital signals inputted via the respective latch circuits 5, the digital signal processing including code conversion for converting the thermometer code into a binary code, linearity correction for correcting an actual output signal of the latch circuit 5 to an ideal output signal characteristic of the latch circuit 5, filtering process for freely changing over a frequency characteristic by limiting a frequency band upon integrating, for example, a digital filter in the digital processing circuit 8, and so forth, thereby outputting A/D conversion data to a digital signal output terminal Dout 9.

In the case of integrating the digital filter in the digital processing circuit 8, the frequency characteristic can be freely changed over by limiting a frequency band. For example, if a low-frequency component is to be taken out of a high-frequency component inputted to the digital processing circuit 8, the low-frequency component alone can be outputted by applying low-pass filtering to the digital processing circuit 8.

Further, by latching respective outputs of the parallel-connected comparators 1 by the agency of a plurality of clock signals inputted to the respective latch circuits 5, the clock signals having a phase shifted respectively, and by delaying an analog signal Ain inputted to the parallel-connected comparators 1 by the predetermined time length, respectively, interleaving (multiplexing) can be accomplished, thereby achieving speed-up in operation of the A/D converter.

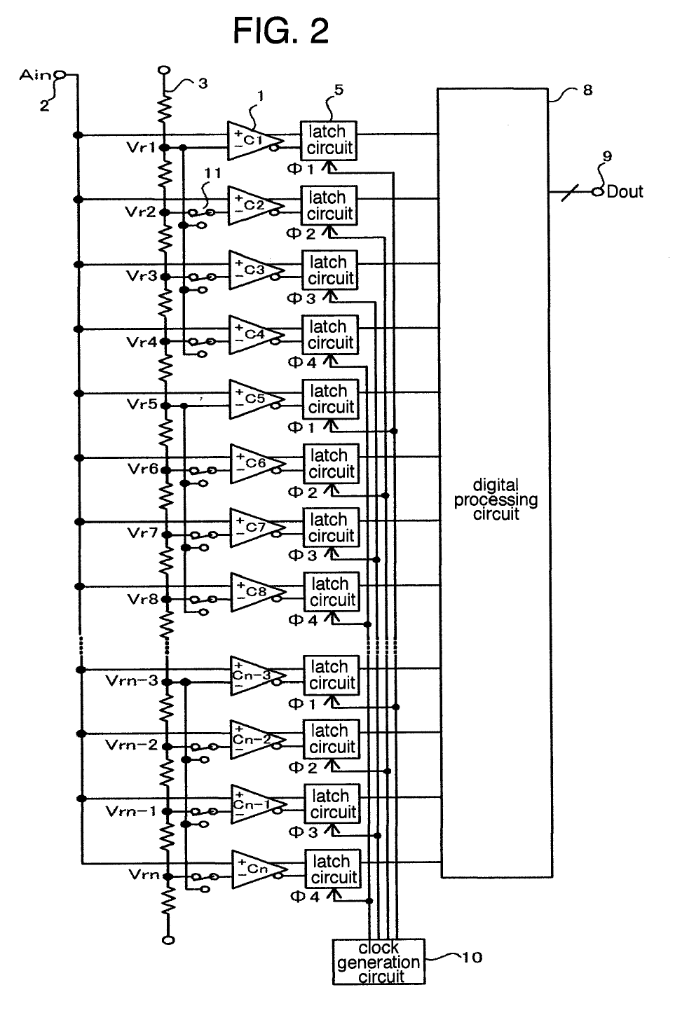

FIG. 2 is a block diagram of an A/D converter showing one embodiment of a high resolution mode according to the invention, and in the figure, parts corresponding to those in FIG. 1 are denoted by like reference numerals. In FIG. 2, a plurality (n units) of comparators 1 are configured such that every 4 units thereof, arranged in sequence, are grouped, and a reference voltage inputted to the other of the input terminals of each of the comparators 1 is changed over on a group-by-group basis. More specifically, changeover switches 11 concurrently and operatively connected to each other are connected to the other of the input terminals of lower 3 units of the comparators 1 of each group, respectively, and respective output voltages of resistance-type potential dividers 3 are inputted to one of fixed contacts of the respective changeover switches 11 while the reference voltage of the uppermost comparator 1 of each group is inputted to the other of the fixed contacts of the respective changeover switch 11.

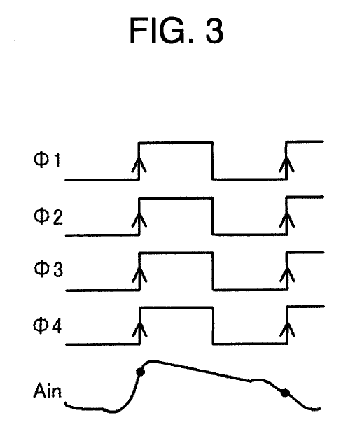

A clock generation circuit 10 inputs clock signals Φ1 to Φ4, identical in phase to each other, as shown in a waveform chart of FIG. 3, to the latch circuits 5 corresponding to the respective groups. By so doing, respective output signals of the comparators 1 for digitizing the analog signal Ain are latched by the agency of the respective clock signals identical in phase to each other. In FIG. 2, the movable contact of the changeover switch 11 is connected to an output voltage side of each of resistance-type potential dividers 3, however, if the movable contact is set to a reference voltage side on a group-by-group basis, interleaving as well can be coped with.

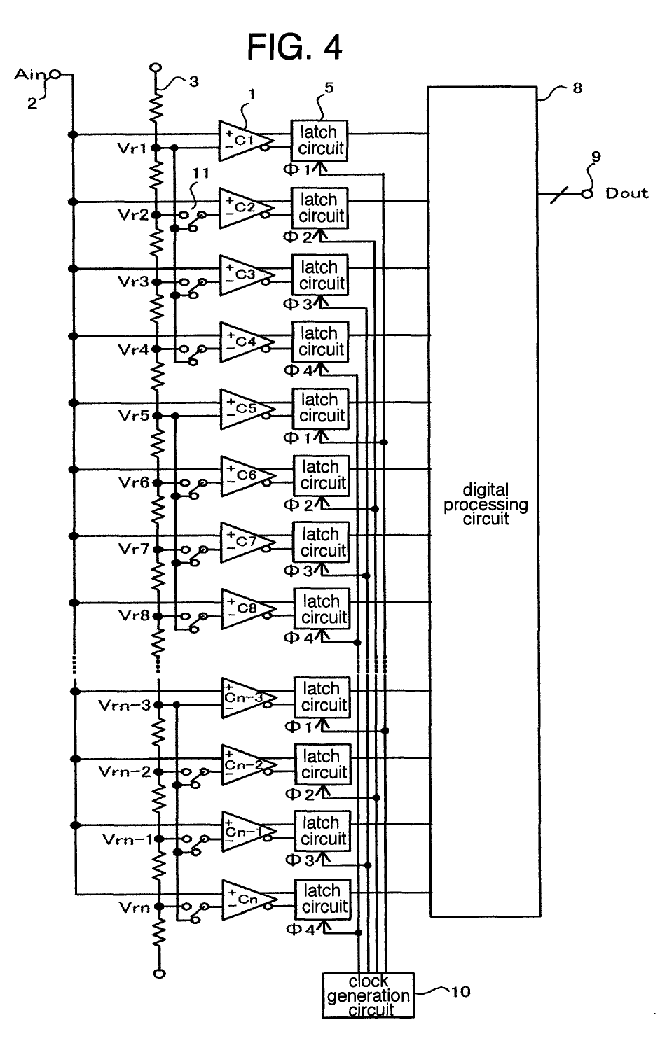

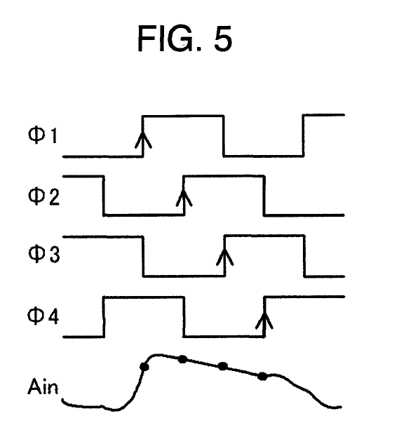

FIG. 4 is a block diagram of an A/D converter showing one embodiment of a high-speed conversion mode according to the invention, and in the figure, parts corresponding to those in FIG. 2 are denoted by like reference numerals. In FIG. 4, a clock generation circuit 10 inputs 4-phase clock signals Φ1 to Φ4, differing in phase from each other by the ¼ phase, as shown in a waveform chart of FIG. 5, to the respective latch circuits 5 corresponding to the respective groups. A movable contact of a switch 11 is connected to a reference voltage side on a group-by-group basis. By so doing, respective output signals of the comparators 1 for digitizing the analog signal Ain are latched by the agency of the respective clock signals differing in phase from each other by the ¼ phase, thereby implementing interleaving.

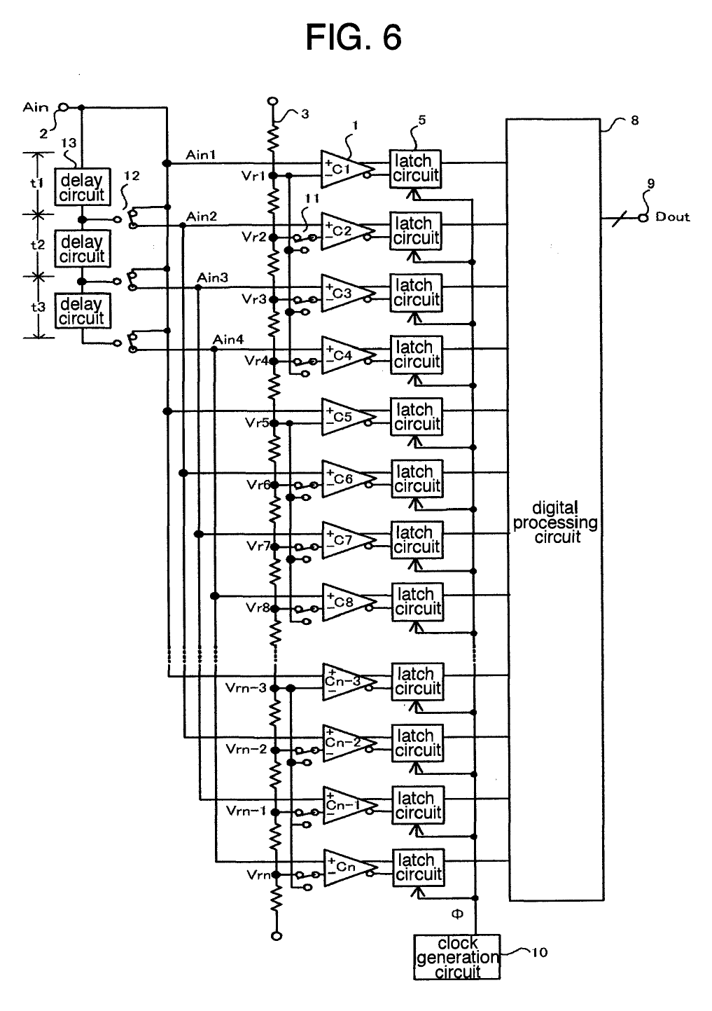

FIG. 6 is a block diagram of an A/D converter showing another embodiment of a high-speed conversion mode according to the invention, and in the figure, parts corresponding to those in FIG. 2 are denoted by like reference numerals. In FIG. 6, an input system for an analog signal Ain is provided with 3 units of changeover switches 12 concurrently and operatively connected to each other, and 3 units of delay circuits 13 connected in series, the delay circuits each having delay time of a ¼ period such that a phase of the analog signal Ain inputted to one of input terminals of each comparator 1 for every 4 units of a plurality (n units) of comparators 1, arranged in sequence, and grouped together, is delayed by the ¼ period according to the order of arrangement within each group.

More specifically, one end of each of the 3 units of the delay circuits 13 connected in series is connected to an input terminal 2 of the analog signal Ain, the other end thereof is connected to one of fixed contacts of the lowermost switch of the 3 units of the changeover switches 12, a node between the uppermost delay circuit 13 and the intermediate delay circuit 13 is connected to one of fixed contacts of the uppermost switch, and a node between the intermediate delay circuit 13 and the lowermost delay circuit 13 is connected to one of fixed contacts of the intermediate switch. The other of the contact points of each of the 3 units of changeover switches 12 is connected to the input terminal 2 of the analog signal Ain, a movable contact of the uppermost switch is connected to one of input terminals of the second comparator 1 from the top in each group, a movable contact of the intermediate switch is connected to one of input terminals of the third comparator 1 from the top in each group, and a movable contact of the lowermost switch is connected to one of input terminals of the lowermost comparator 1 in each group. In FIG. 6, a movable contact of the switch 11 is connected to an output voltage side of each of the resistance-type potential dividers 3, and a movable contact of each of the changeover switches 12 is connected to the input terminal 2 of the analog signal Ain.

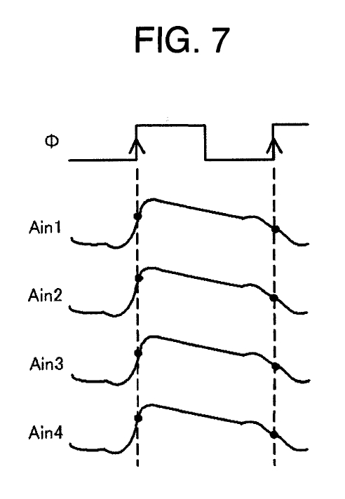

A clock generation circuit 10 inputs a common clock signal Φ to the respective latch circuits 5. By so doing, respective output signals of the comparators 1 for digitizing the analog signals Ain1 to Ain4, respectively, are latched by the agency of the common clock signal Φ as shown in a waveform chart of FIG. 7.

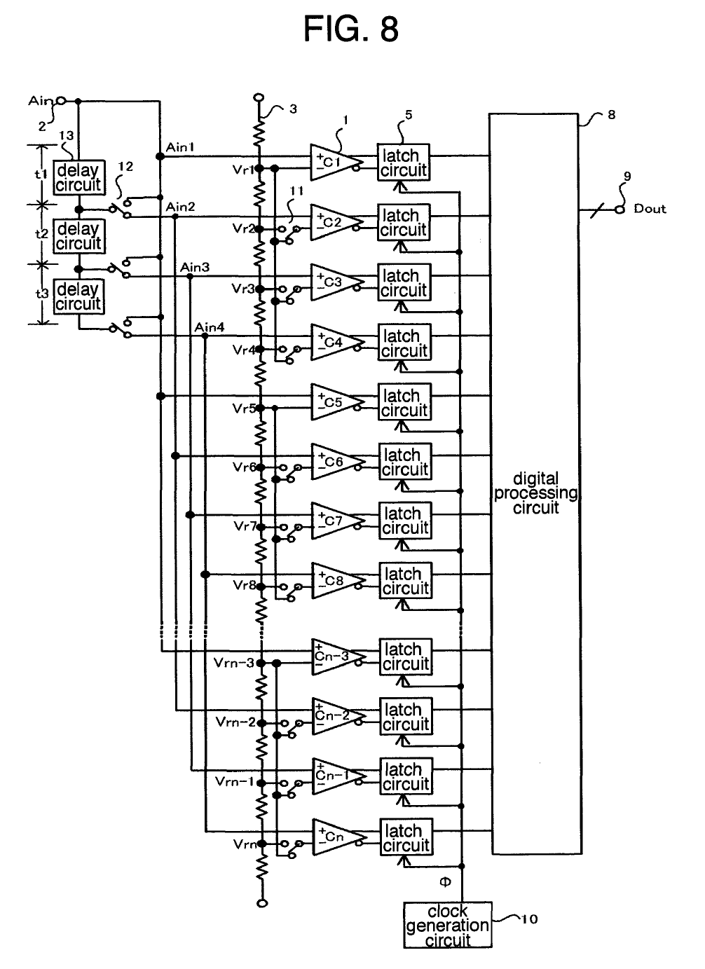

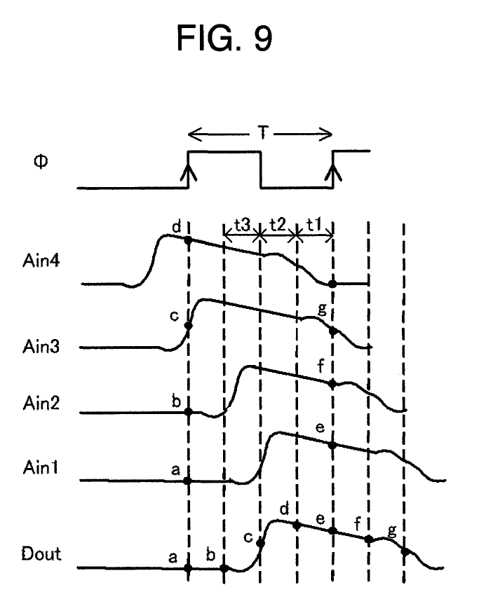

FIG. 8 is a block diagram of an A/D converter showing still another embodiment of a high-speed conversion mode according to the invention, and in the figure, parts corresponding to those in FIG. 6 are denoted by like reference numerals. In FIG. 8, a movable contact of a switch 11 is connected to a reference voltage side on a group-by-group basis, and a movable contact of a changeover switch 12 is connected to a delay circuit 13 side. By so doing, the analog signals Ain1 to Ain4 delivered to parallel-connected comparators 1, respectively, are delayed from each other by the delay circuits 13 by the ¼ period (t1 to t3), and reference voltages Vr delivered to the parallel-connected comparators 1, respectively, become identical on a group-by-group basis. The common clock signal Φ from the clock generation circuit 10 has been delivered to the respective latch circuits 5. As a result, the same interleaving as referred to in FIG. 4 can be implemented as shown in a waveform chart of FIG. 9.

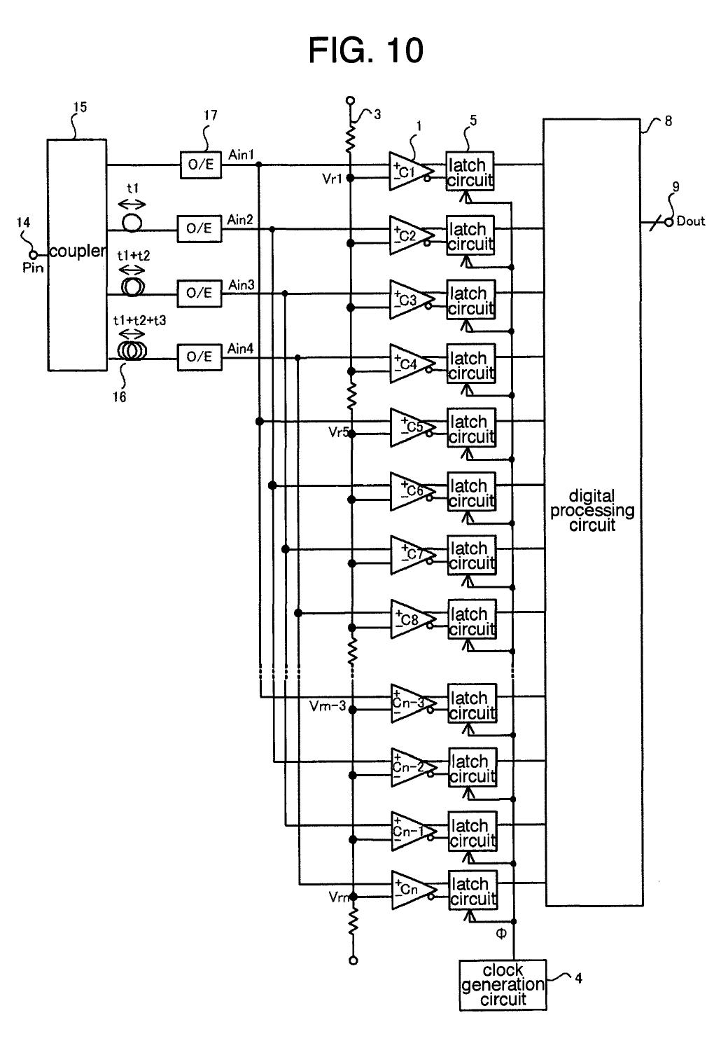

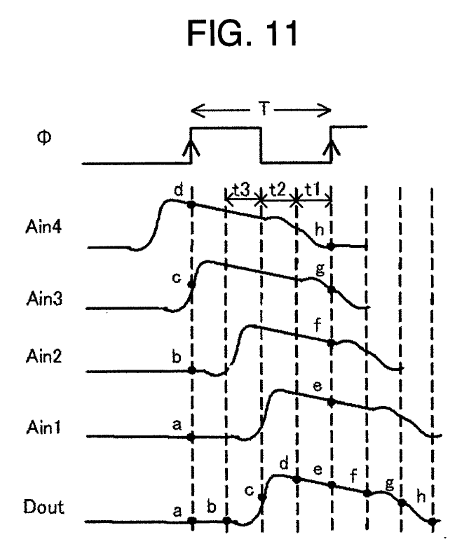

FIG. 10 is a block diagram of an A/D converter made up such that an optical signal Pin in place of the analog signal Ain shown in FIG. 8 can be inputted thereto, and in the figure, parts corresponding to those in FIG. 8 are denoted by like reference numerals. More specifically, the optical signal Pin inputted to an optical signal input 14 is caused to branch off by a coupler 15 to be inputted to O/E converters 17 for converting an optical signal into an electric signal via optical fiber delay lines 16 for delaying optical signals by the predetermined time (t1, t1+t2, t1+t2+t3), respectively, whereupon electric signals Ain1 to Ain4, converted by, and outputted from the respective O/E converters 17, are inputted to respective comparators 1. Respective output signals of the comparators 1 are latched by respective latch circuits 5 to which a common clock signal Φ from a clock generation circuit 4 has been delivered as is the case with FIG. 8. By so doing, interleaving for the optical signal Pin can be implemented as shown in a waveform chart of FIG. 11.

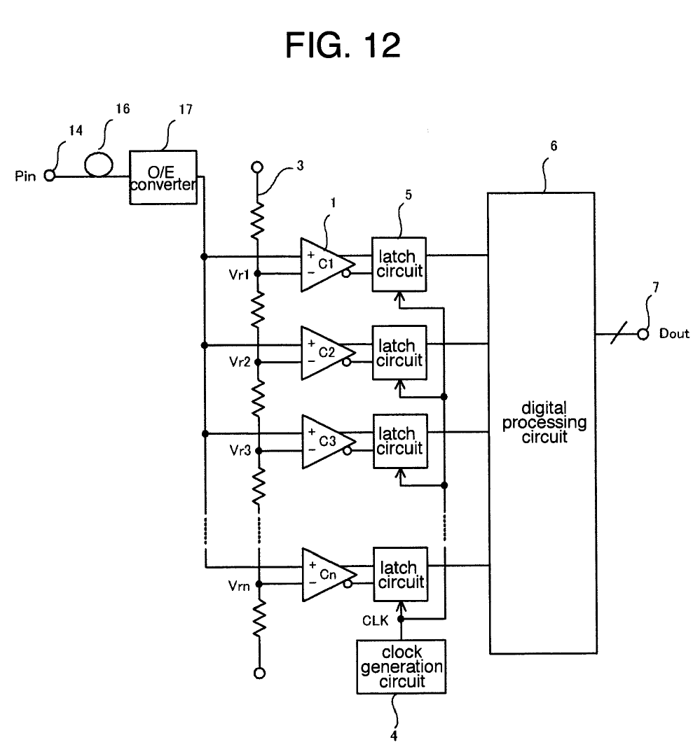

FIG. 12 is a block diagram of an A/D converter made up such that an optical signal Pin in place of the analog signal Ain shown in FIG. 1 can be inputted thereto. More specifically, the optical signal Pin delivered to an optical signal input 14 is inputted to an O/E converter 17 for converting an optical signal into an electric signal via an optical fiber delay line 16, whereupon the electric signal converted by, and outputted from the O/E converter 17 are inputted to respective comparators 1. As in the case with FIG. 1, respective output signals of the comparators 1 are latched by respective latch circuits 5 to which a common clock signal CLK from a clock generation circuit 4 has been delivered. By so doing, an optical A/D converter can be accomplished.

Further, by preparing in advance a switching circuit for the clock signal to be inputted to the respective comparators 1 connected in parallel with each other, it is possible to freely change over the A/D converter between a slow-high resolution type, and a fast-low resolution type. In such a case, data composition is executed by the digital processing circuit 8.

Still further, the latch circuits 5 may be installed in the digital processing circuit 8.

Yet further, for the digital processing circuit 8, use may be made of software means such as FPGA (Field Programmable Gate Array), CPLD (Complex Programmable Logic device), or CPU, and so forth.

Furthermore, for the digital processing circuit 8, respective functions of an encoder, a digital filter, a linearity correction circuit, a clock changeover circuit, and so forth may be combined together.

If the digital processing circuit 8 is made up of a programmable circuit, this will enable changeover in function (a change in specification) after delivery of a product with greater ease, rendering it possible to effect a change in function even in the field. Further, it is also possible to change characteristics of an A/D converter under control from CPU.

Furthermore, the parallel-connected comparators and the digital processing circuit 8 may be mounted on a common semiconductor substrate, thereby making up a semiconductor in one package.

As described in the foregoing, with the present invention, by combining comparators with a programmable circuit, it is possible to accomplish an A/D converter capable of changing its specification and function with the use of the programmable circuit. With the A/D converter, there is no need for changing hardware even in the case of a change in specification, and a change in specification in the field can be coped with.

What is claimed is:

1. An A/D converter comprising:
a parallel-connected comparison circuit including a plurality of comparators, an analog signal being inputted to one of input terminals of the respective comparators while respective predetermined reference voltages being inputted to the other of the input terminals of the respective comparators, and
a digital processing circuit for receiving output signals from the parallel-connected comparison circuit, and executing predetermined digital processing as set on the basis of a program.

2. The A/D converter according to claim 1, wherein the predetermined reference voltages is a common predetermined voltage.

3. The A/D converter according to claim 1, wherein analog voltages differing from each other are inputted to one of the input terminals of the respective comparators.

4. The A/D converter according to claim 1, wherein the digital processing circuit is a programmable circuit.

5. The A/D converter according to claim 1, wherein the processing circuit executes digital processing including at least any of code conversion, linearity correction, and filtering process.

6. The A/D converter according to claim 1, wherein the digital processing circuit is made up of FPGA.

7. The A/D converter according to claim 1, wherein the digital processing circuit is made up of CPLD.

8. The A/D converter according to claim 1, wherein the parallel-connected comparison circuit and the digital processing circuit are mounted on a common semiconductor substrate.
